(19) United States
(12) Patent Application Publication
(10) Pub. No.: US 2012/0208333 A1
(43) Pub. Date: Aug. 16, 2012

(54) METHOD FOR FABRICATING SEMICONDUCTOR DEVICE

(75) Inventors: An Bae LEE, Seoul (KR); Seung Woo JIN, Icheon-si (KR); Yung Hwan JOO, Seoul (KR); Il Sik JANG, Icheon-si (KR); Jae Chun CHA, Icheon-si (KR)

(73) Assignee: HYNIX SEMICONDUCTOR INC., Icheon-si (KR)

(21) Appl. No.: 13/360,051

(22) Filed: Jan. 27, 2012

(30) Foreign Application Priority Data
Feb. 14, 2011 (KR) 10-2011-0012892

(51) Int. Cl. H01L 21/8238; H01L 21/265

(52) U.S. Cl. 438/231; 438/527; 257/E21.334; 257/E21.634

(57) ABSTRACT

A method for fabricating a semiconductor device includes: forming an impurity junction area within an area of the semiconductor substrate; forming a contact hole which partially exposes a surface the impurity junction area; and performing an additional ion implant process to implant impurity ions into the impurity junction area exposed through the contact hole, thereby increasing an impurity concentration of a surface portion of the impurity junction area.

### CROSS-REFERENCES TO RELATED APPLICATIONS

The present application claims priority under 35 U.S.C 119(a) to Korean Application No. 10-2011-0012892, filed on Feb. 14, 2011 in the Korean intellectual property Office, which is incorporated herein by reference in its entirety set forth in full.

### BACKGROUND

1. Field of the Invention

Embodiments of the present invention relate to a method for fabricating a semiconductor device, and more particularly to minimizing defects occurring during the fabrication process.

2. Description of the Related Art

During a semiconductor fabrication process, a channel area is formed inside a silicon substrate, a source area and a drain area of a transistor are defined, and a contact plug is then formed over the silicon substrate. The contact plug may be contacted with the source area and the drain area of the transistor, in order to receive power from outside and supply a current to another device. Typically, the contact plug is formed of a metallic material. Before forming the contact plug, an ion implant process is performed to implant a dopant into the silicon substrate through an exposed surface of the silicon substrate. The ion implant process is performed to reduce contact resistance between the contact plug and the source and drain areas and control a threshold voltage of the transistor to a desired level. Such an ion implant process is performed by physically implanting a dopant into the silicon substrate.

However, during the ion implant process to implant a dopant into the silicon substrate, defects may be formed inside the silicon substrate. The defects may be formed while silicon (Si) couplings within the silicon substrate are cut during the ion implant process. As such, when impurities are diffused while the defects are formed within the silicon substrate congregate, an impurity concentration of the surface of the silicon substrate decreases. When the impurity concentration of the surface of the silicon substrate decreases, the contact resistance between silicon and a metallic material forming the contact plug increases, and the current characteristic of the transistor is degraded. Accordingly, it becomes difficult to control the threshold voltage of the transistor.

### SUMMARY

An embodiment of the present invention relates to a method for fabricating a semiconductor device, which may improve the characteristic of a device by controlling the position of defects formed during an ion implant process, and minimize contact resistance at a contact portion with a contact plug by preventing transient enhanced diffusion (TED) of impurity ions caused by physical damage, thereby implementing a high-speed device.

In one embodiment, a method for fabricating a semiconductor device includes: forming an impurity junction area within an area of a semiconductor substrate; forming a contact hole which partially exposes a surface of the impurity junction area; and performing an additional ion implant process to implant impurity ions into the impurity junction area exposed through the contact hole, thereby increasing an impurity concentration of a surface portion of the impurity junction area.

The method may further include: performing a heat treatment process to diffuse the impurity ions implanted into the impurity junction area; and filling the contact hole with a conductive material to form a contact which is directly contacted with the impurity junction area, after performing the additional ion implant process.

Performing the additional ion implant process may include forming an amorphous layer at a first depth from the surface of the impurity junction area through a cold implant process for implanting impurity ions at an ultralow temperature of −100° C. to −200° C., such that defects formed during the additional ion implant process are positioned under the interface between the amorphous layer and the semiconductor substrate.

The cold implant process may include: disposing the semiconductor substrate over a chuck of an ion implant device; and implanting impurity ions in a state in which the temperature of the chuck is reduced to an ultralow temperature of −100° C. to −200° C. to cool down the semiconductor substrate to an ultralow temperature of −100° C. to −200° C.

In the implanting of the impurity ions, the semiconductor substrate is cooled down by flowing a refrigerant to the chuck or contacting a medium having a refrigerant flowed therein with the chuck.

The heat treatment process may include a rapid thermal annealing (RTA) process in which ammonia (NH₃) gas is supplied together.

Performing the additional ion implant process may include recrystallizing defects formed during the additional ion implant process, through a hot implant process for implanting impurity ions at a temperature of 100° C. to 500° C.

The hot implant process may include: disposing the semiconductor substrate over a chuck of an ion implant device; and implanting impurity ions in a state in which the temperature of the semiconductor substrate is increased to the temperature of 100° C. to 500° C. by heating the chuck through a heating wire mounted on the chuck or heating the chuck using radiant heat.

The impurity ions may include cluster ions or molecular ions containing n-type or p-type conductive impurities. The n-type conductive impurities may include phosphorous (P) or arsenide (As), and the p-type conductive impurities may include boron (B) or BF₂. The impurity ions may be implanted in a state in which ion implant energy is set at 1 KeV to 10 KeV and a dose rate is set at 1E13 to 1E16 ions/cm³.

In another embodiment, a method for fabricating a semiconductor substrate includes: forming an n-type poly gate and a p-type poly gate over a semiconductor substrate having an n-type area and a p-type area such that the n-type poly gate is formed in the n-type area and the p-type poly gate is formed in the p-type area; forming a gate spacer on both side surfaces of the n-type and p-type poly gates; forming an impurity junction area within an active area of the semiconductor substrate at both side surfaces of the n-type and p-type poly gates; forming an interlayer dielectric layer including a contact hole which partially exposes a surface of the impurity junction area at both side surfaces of the n-type and p-type poly gates; performing an ion implant process on the surface of the impurity junction area exposed through the contact hole to increase an impurity concentration of a surface portion of the active area, the ion implant process including a cold implant process or a hot implant process; performing a heat treatment process to diffuse the impurity ions implanted into the impurity junction area; and filling the contact hole with a conductive material to form a contact which is directly contacted with the impurity junction area.

In still another embodiment, a method for fabricating a semiconductor device comprises forming an impurity junction area within an area of a semiconductor substrate; and performing at least two ion implant processes for implanting impurities into the impurity junction area, where one ion implant process is performed at a temperature that is one of less than −100° C. or greater than 100° C.

### BRIEF DESCRIPTION OF THE DRAWINGS

The above and other aspects, features and other advantages will be more clearly understood from the following detailed description taken in conjunction with the accompanying drawings, in which:

FIGS. 1 to 13 are diagrams explaining a method for fabricating a semiconductor in accordance with an embodiment of the present invention;

FIG. 14 is a graph showing concentration distributions of impurity ions according to the temperature during an ion implant process; and

FIGS. 15 to 18 are diagrams explaining a method for fabricating a semiconductor device in accordance with another embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

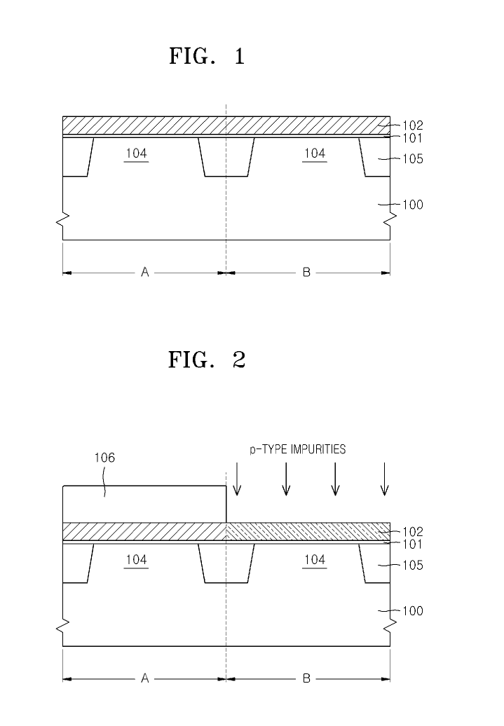

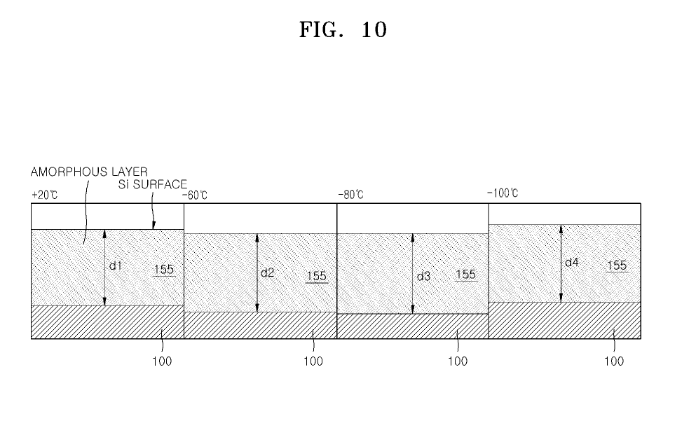

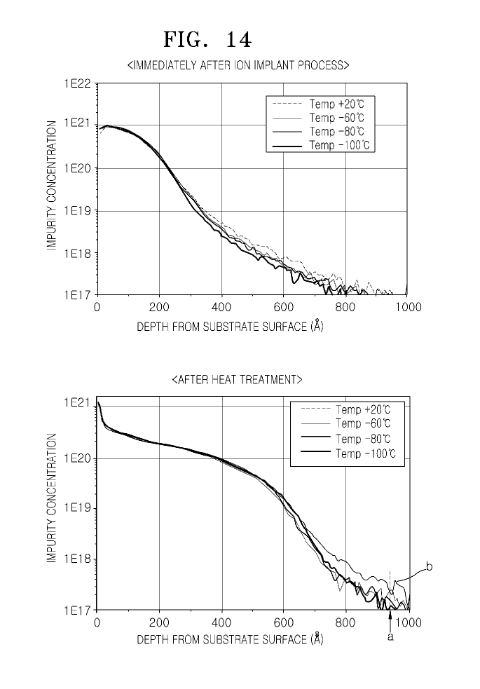

FIGS. 1 to 13 are diagrams explaining a method for fabricating a semiconductor in accordance with an embodiment of the present invention. In particular, FIG. 9 illustrates defects formed in an active area during a general ion implant process. FIG. 10 illustrates changes in a thickness of an amorphous layer according to a performance temperature of an ion implant process. FIG. 14 is a graph showing concentration distributions of impurity ions according to a temperature during the ion implant process.

Referring to FIG. 1, a gate dielectric layer 101 is formed over a semiconductor substrate 100 including first and second areas A and B defined therein. Here, the semiconductor substrate 100 is a peripheral circuit area, the first area A is where an n-type MOS transistor is to be disposed, and the second area B is where a p-type MOS transistor is to be disposed. The semiconductor substrate 100 includes an active area 104 defined by an isolation layer 105. The gate dielectric layer 101 formed over the semiconductor substrate 100 may be formed of oxide through thermal oxidation. Then, a polysilicon layer 102 is formed as a gate conductive layer over the gate dielectric layer 101. The polysilicon layer 102 may be formed of polysilicon doped with n-type impurity ions. At this time, phosphorus (P) may be used as the n-type impurity ions, but other n-type conductive ions such as arsenide (As) may be used in some cases. The doping of the n-type impurity ions into the polysilicon layer 102 may be performed by the following process: polysilicon is deposited, and a separate n-type impurity ion doping process is then performed. Alternatively, the polysilicon layer 102 may be deposited while doping n-type impurity ions.

Referring to FIG. 2, a mask layer pattern 106 is formed to expose the second area B of the semiconductor substrate 100. The mask layer pattern 106 may be formed of a resist material. For this structure, a resist layer is formed over the semiconductor substrate 100. Then, a lithography process including an exposure and development process is performed to form the mask layer pattern 106 which exposes the polysilicon layer 102 of the second area B in the semiconductor substrate 100 and blocks the other area including the first area A. Using the mask layer pattern 106 as an ion implant barrier layer, an ion implant process is performed to implant impurity ions into the exposed polysilicon layer 102 of the second area B. The impurity ions may include p-type impurity ions, for example, boron (B). The mask layer pattern 106 blocking the first area A of the semiconductor substrate 100 where the ion implant process was performed is removed. The mask layer pattern 106 may be removed by a strip process. A heat treatment process is performed on the semiconductor substrate 100 to activate the p-type impurity ions implanted into the polysilicon layer 102 of the second area A.

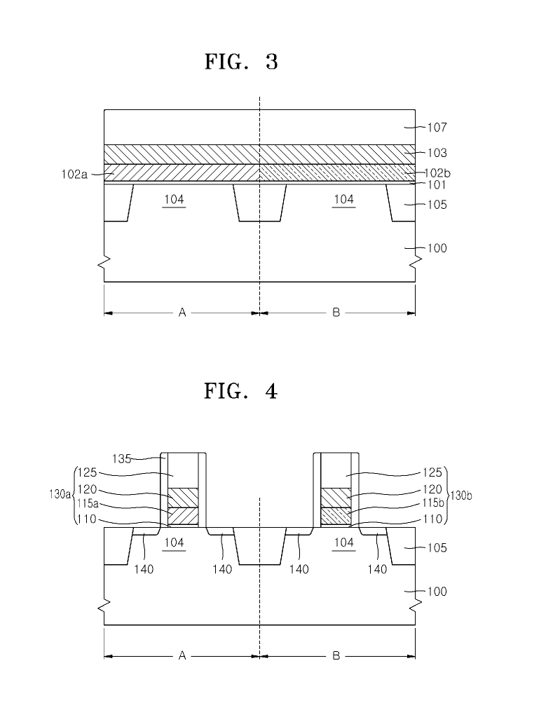

Referring to FIG. 3, while the impurity ions implanted into the polysilicon layer 102 are activated by the heat treatment process, an n-type polysilicon layer 102a is formed in the first area A, and a p-type polysilicon layer 102b is formed in the second area B. A gate metal layer 103 and a hard mask layer 107 are sequentially formed over the semiconductor substrate 100 having the n-type polysilicon layer 102a and p-type polysilicon layers 102b formed therein. The gate metal layer 103 may include tungsten (W) or tungsten silicide (WSix). Furthermore, although not illustrated in the drawing, a tungsten nitride layer (WN) may be formed between the gate metal layer 103 and the polysilicon layers (102a and 102b), in order to substantially prevent conductive materials of the polysilicon layers (102a and 102b) from diffusing. The hard mask layer 107 is formed of nitride, and serves to protect the lower layers during a subsequent etching process for forming a gate pattern.

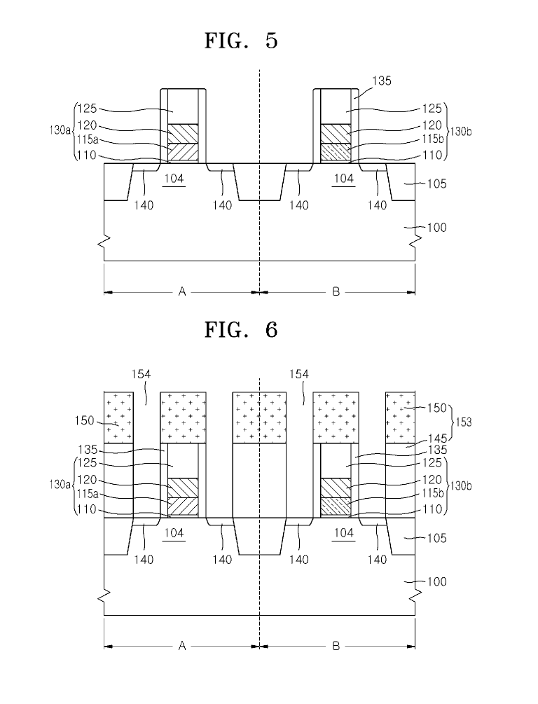

Referring to FIG. 4, a resist material is applied onto the hard mask layer 107 and then patterned to form a resist pattern (not illustrated) which defines an area where a gate pattern is to be formed. Continuously, the lower layers are etched using the resist pattern as a mask, until the surface of the semiconductor substrate 100 is exposed. Then, an n-type poly gate 130a is formed in the first area A, and a p-type poly gate 130b is formed in the second area B. Here, the n-type poly gate 130a formed in the first area A has a stacked structure of a gate dielectric layer pattern 110, an n-type polysilicon pattern 115a, a gate metal layer pattern 120, and a hard mask pattern 125. The p-type poly gate 130b formed in the second area B has a stacked structure of a gate dielectric layer pattern 110, a p-type polysilicon pattern 115b, a gate metal layer pattern 120, and a hard mask pattern 125. A spacer 135 may be formed on sidewalls of the poly gates 130a and 130b as will be further described in relation to FIG. 5.

Referring to FIG. 5, a spacer 135 is formed on both sidewalls of the n-type poly gate 130a formed in the first area A of the semiconductor substrate 100 and both sidewalls of the p-type poly gate 130b formed in the second area B. The spacer 135 formed on the sidewalls of the poly gates 130a and 130b serves to heal damage caused by plasma which is generated during the etching process for forming the poly gates 130a and 130b, and the spacer 135 may also minimize a short channel effect (SCE) which occurs as the device is reduced in size. Considering stress applied to the poly gates 130a and 130b and convenience of a subsequent process, the spacer 135 may have a stacked structure including one or more nitride layers or oxide layers. Using the spacer 135 as an ion implant barrier layer, an ion implant process is performed to form a junction area 140 which may be an impurity junction area, the junction area 140 including a source area and a drain area inside the active area 104 of the semiconductor substrate 100 at both side surfaces of the n-type and p-type poly gates 130a and 130b.

Referring to FIG. 6, an interlayer dielectric layer 153 is formed. The interlayer dielectric layer 153 includes contact holes 154 which expose the junction areas 140 of the semiconductor substrate 100. For this structure, an interlayer dielectric layer 153 is first formed on the entire surface of the semiconductor substrate 100 having the n-type and p-type poly gates 130a and 130b formed therein. In this case, since a self align contact (SAC) process is applied to align the interlayer dielectric layer 153 along the shape of the spacer 135 attached to both sidewalls of the p-type and n-type poly gates 130a and 130b during a subsequent etching process for forming the contact hole 154, the interlayer dielectric layer 153 may be formed of a material having a different etching selectivity than the material forming the spacer 135. For example, when the outermost layer of the spacer 135 having a stacked structure of one or more nitride layers or oxide layers is a nitride layer, the interlayer dielectric layer 153 may be formed of an oxide layer. Alternatively, when the outermost layer of the spacer 135 is an oxide layer, the interlayer dielectric layer 153 may be formed of a nitride layer. Furthermore, the interlayer dielectric layer 153 may be formed of an amorphous carbon layer. Here, the interlayer dielectric layer 153 may have a stacked structure of first and second interlayer dielectric layer 145 and 150 including one or more of the oxide layer, the nitride layer, and the amorphous carbon layer. The interlayer dielectric layer 153 is selectively etched to form the contact holes 154 exposing the junction areas 140. Here, the junction areas 140 exposed through the contact hole 154 is contacted with a metal contact which is subsequently formed to couple an external input terminal to the active areas 104 of the semiconductor substrate 100.

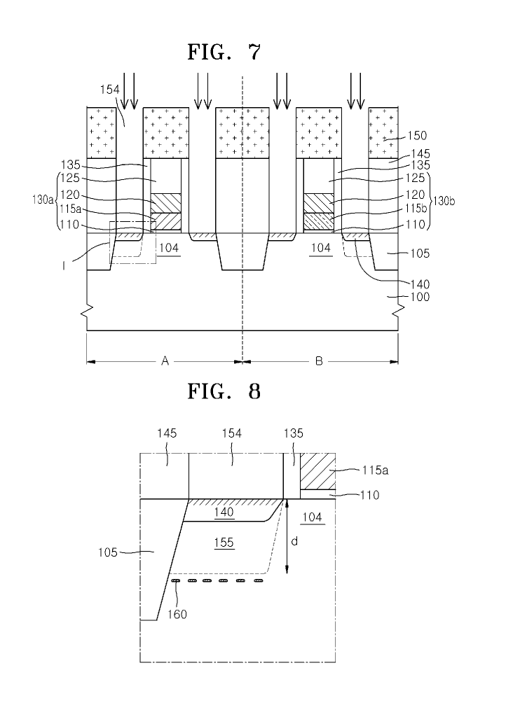

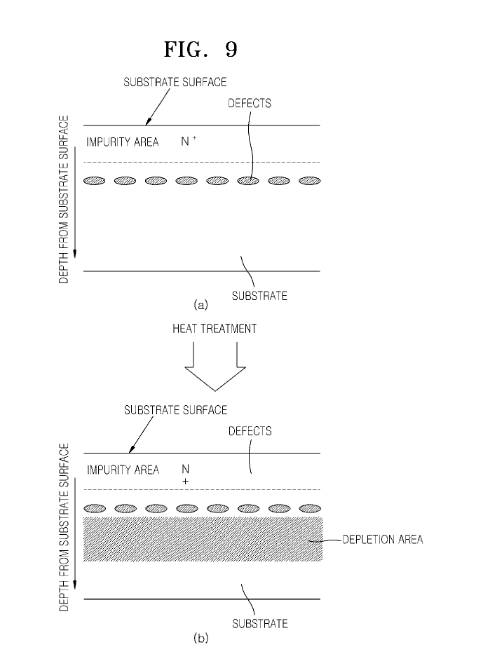

Referring to FIGS. 7 and 8, an additional ion implant process for implanting impurity ions into the exposed junction area 140 of the semiconductor substrate 100 is performed to form an amorphous layer 155 at a first thickness d from the junction areas 140. The impurity ions are indicated by slashes. The additional ion implant process is performed by a cold implant process to implant impurity ions at an ultralow temperature of −100 to −200° C.

The additional ion implant process is performed on the junction areas 140 formed in the active area 104 of the semiconductor substrate 100, in order to reduce contact resistance with a metal contact and control the threshold voltage of a transistor to a desired level. The impurity ions are implanted into the active area by a physical ion implant process. In general, an ion implant process is performed at ion implant energy of 700 KeV. In this case, however, silicon (Si) of the substrate may be dissolved to cause a fail in a device. Therefore, while the temperature of the entire semiconductor substrate is maintained at 20° C. and the rear surface of a wafer is cooled to prevent the temperature from increasing to 60° C. or more, the ion implant process is performed to suppress the formation of an amorphous layer. However, as silicon couplings within the semiconductor substrate are cut while the impurity ions are implanted into the semiconductor substrate by a physical ion implant process, a plurality of defects are formed inside the wafer. The defects formed in the wafer may include a point defect or dislocation defect.

FIG. 9A illustrates defects formed in the active area through the general ion implant process. Referring to FIG. 9A, defects are formed in the silicon substrate adjacent to an impurity area doped with n⁺ conductive impurity ions, immediately after the ion implant process. When a heat treatment process for diffusing the impurity ions is performed in a state in which such defects are formed, transient enhanced diffusion (TED) may occur which may increase the diffusion of the impurity ions. Referring to FIG. 9B, the TED refers to a phenomenon in which the impurity ions are diffused into a wider area than a predetermined area. When the TED occurs, the impurity concentration of the surface of the semiconductor substrate decreases. When the impurity concentration decreases, contact resistance between the semiconductor substrate and a metal contact which is directly contacted with the impurity area is increased, and a threshold voltage is changed. Consequently, a current characteristic may be degraded.

In an embodiment of the present invention, the cold implant process for implanting impurity ions at an ultralow temperature of −100 to −200° C. is introduced instead of the ion implant process which is performed to suppress the formation of an amorphous layer while maintaining the temperature of the entire semiconductor substrate at 20° C. to 60° C. The cold implant process for implanting impurity ions at an ultralow temperature of −100 to −200° C. is introduced in order to suppress the increase of contact resistance and the change of a threshold voltage which may occur due to defects formed in the wafer during the physical ion implant process.

In order to perform the additional ion implant process on the exposed junction areas 140 of the semiconductor substrate 100, the semiconductor substrate 100 is disposed over a chuck (not illustrated) of an ion implant device. During the additional ion implant process, cluster ions or molecular ions containing n-type or p-type conductive impurities may be implanted. For example, the p-type conductive impurities may include B or BF₂ ions, and the n-type conductive impurities may include P or As. The additional ion implant process may be performed in a state in which the ion implant energy is set at 1 KeV to 10 KeV and a dose rate is set at 1E13 to 1E16 ions/cm³. During the cold implant process, the temperature of the chuck of the ion implant device having the semiconductor substrate 100 disposed thereon is maintained at −100 to −200° C.

Accordingly, the temperature of the semiconductor substrate 100 is decreased to −100 to −200° C. such that the impurity ions are implanted at a low temperature. In this case, the semiconductor substrate 100 may be cooled by flowing a refrigerant to the chuck or contacting a medium having a refrigerant flowed therein with the chuck. At this time, the ion implant energy may be changed by ±10%.

When the general ion implant process is performed while the temperature of the entire semiconductor substrate is maintained at 20 to 60° C., silicon couplings of the semiconductor substrate are cut, and the cut silicon atoms are rearranged, that is, recrystallization occurs. Accordingly, the formation of an amorphous layer is suppressed. However, when the ion implant process is performed at a low temperature, energy for recrystallization is not generated. Therefore, recrystallization does not occur, but only an amorphous layer is formed. In this embodiment of the present invention, the cold implant process for implanting impurity ions at an ultralow temperature of −100 to −200° C. is performed to increase the thickness of the amorphous layer.

FIG. 8 is an expanded view of a region I including a junction area of FIG. 7. Referring to FIG. 8, when the additional ion implant process for implanting impurity ions at an ultralow temperature of −100 to −200° C. is performed, the amorphous layer 155 is formed to a first thickness d, for example, 238 Å from the surface of the junction area 140. Also, the additional ion implant process for implanting impurity ions at an ultralow temperature may suppress recrystallization. Furthermore, the defects 160 formed during the ion implant process are positioned under the amorphous layer 155. The amorphous layer 155 is formed to a larger thickness as the performance temperature of the ion implant process decreases. FIG. 10 shows changes in thickness of the amorphous layer according to the performance temperature of the ion implant process. Referring to FIG. 10, it is observed that, when the ion implant process is performed at a temperature of +20° C. corresponding to the temperature of the general ion implant process, the amorphous layer 155 is formed to a thickness d1 of 208.5 Å. However, as the temperature of the ion implant process is decreased to −60 to −80° C., the thicknesses d2 and d3 of the amorphous layer 155 are increased to 215 Å and 224.4 Å, respectively. Furthermore, as the temperature is decreased to −100° C., the thickness d4 of the amorphous layer 155 is increased to 238.5 Å. The ion implant process of FIG. 10 was performed in a state in which P ions are applied as the impurity ions and the ion implant energy is set to 10 KeV.

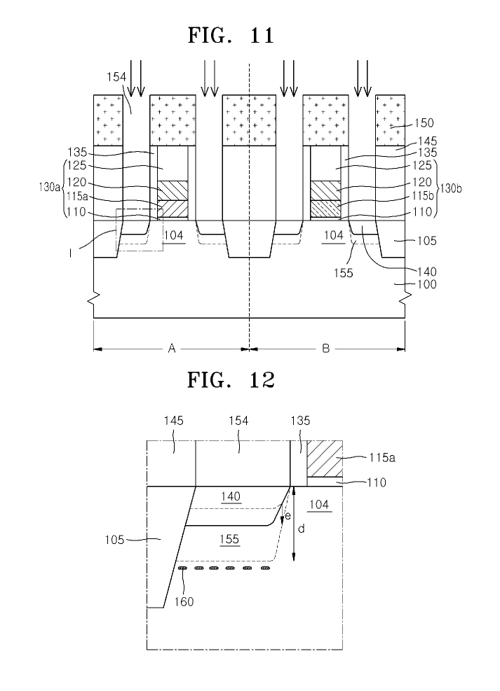

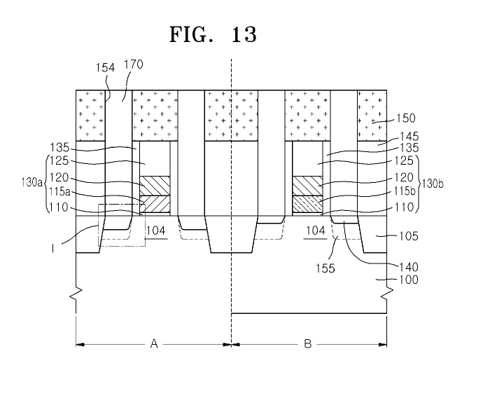

Referring to FIG. 11, a heat treatment process is performed to activate the impurity ions implanted into the exposed junction area 140 by the additional ion implant process. The heat treatment process may include a rapid thermal annealing (RTA) process, but is not limited thereto. The RTA process may be performed by supplying ammonia (NH₃) gas together. FIG. 12 is an expanded view of a region I including a junction area 140 of FIG. 11. Referring to FIG. 12, when a heat treatment process is performed to activate and diffuse the impurity ions implanted into the junction area 140, the thickness of the junction area 140 is increased by a first depth e in the depth direction of the semiconductor substrate 100. In this case, as the impurity ions are diffused within the thickness d of the amorphous layer 155, the junction area 140 is not influenced by the defects 160 positioned under the interface between the amorphous layer 155 and the semiconductor substrate. Accordingly, it is possible to substantially prevent the TED of the impurity ions caused by the defects. At this time, the heat treatment process may be performed after a titanium (Ti) layer is deposited as a barrier metal layer (not illustrated) on the exposed surface of the contact hole 154. When the heat treatment process is performed after the Ti layer is deposited, the NH₃ gas supplied during the heat treatment process is thermally decomposed into nitrogen (N₂) and hydrogen (H₂) and then reacts with the Ti layer to form titanium silicide (TiSi₂). When carbon and oxygen within the Ti layer are removed after the formation of TiS₂, a silicide layer having low specific resistance is formed.

Referring to an upper graph of FIG. 14 which shows the concentrations of impurity ions according to a depth immediately after the ion implant process. When the ion implant process is performed at +20° C. corresponding to the performance temperature of the general ion implant process, the existence of impurities is observed even at a deeper position than 800 Å from the surface of the semiconductor substrate (Si). However, when the cold implant process is performed at −100° C. in accordance with the embodiment of the present invention, the existence of impurities is observed only at a shallower position than 800 Å. Referring to a lower graph of FIG. 14 which shows the concentrations of impurity ions according to the depth after the heat treatment process, when the ion implant process is performed at +20° C. (b), the existence of impurities is observed even at a position of 1,000 Å from the surface of the semiconductor substrate (Si). However, when the cold implant process (a) is performed at −100° C. in accordance with an embodiment of the present invention, the existence of impurities is not observed at the same position. Accordingly, it can be understood that, while the TED of impurities occurs due to defects during the general ion implant process, the diffusion of impurities is suppressed during the ion implant process in accordance with an embodiment of the present invention. Accordingly, the concentration of impurities existing at the surface of the junction area 140 may be secured to thereby reduce contact resistance with a metal contact which is to be subsequently formed.

Referring to FIG. 13, the contact hole 154 is filled with a metallic material to form a metal contact 170. The metal contact 170 is directly contacted with the junction area 140 of the semiconductor substrate 100, and an ohmic contact is formed to minimize contact resistance between the silicon of the semiconductor substrate 100 and the metal. Here, the metal contact 170 serves to receive an external electrical signal and output the received signal to the active area 104 of the semiconductor substrate 100 or output an electrical signal to the outside.

The cold implant process in accordance with an embodiment of the present invention may minimize residual damage within the semiconductor substrate by maximizing the formation of the amorphous layer which is difficult to form under a general condition of ion implant energy and ion implant amount. The cold implant process in accordance with an embodiment of the present invention may also move defects formed at the surface of the semiconductor substrate to a position under the interface between the amorphous layer and the semiconductor substrate, thereby suppressing the diffusion of impurity ions caused by the defects. Accordingly, as the change in threshold voltage of the transistor caused by the change in the number of ions implanted into a unit area minimizes the fluctuation of the impurity ions, it is possible to improve a mismatch of a sense and amplifier transistor indicating an operation error degree of the device which is caused by a difference in threshold voltage between left and right transistors of the sense and amplifier transistor.

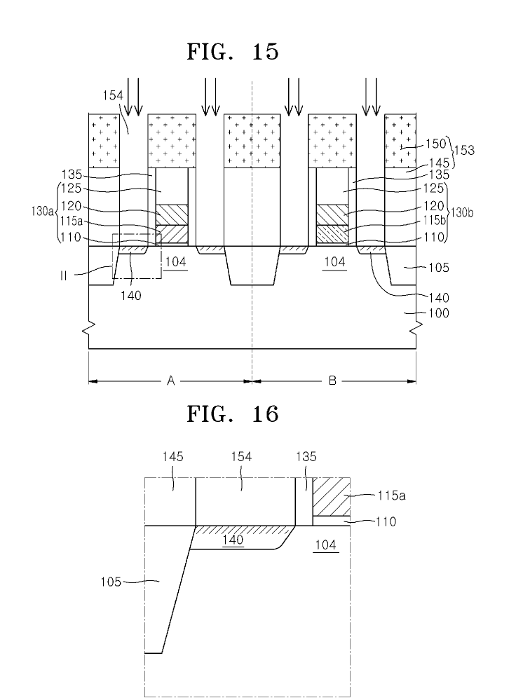

Meanwhile, an ion implant process capable of suppressing the formation of defects within the semiconductor substrate may be introduced to suppress the diffusion of impurity ions caused by the defects. Hereafter, referring to FIGS. 15 to 18, a method for fabricating a semiconductor device in accordance with another embodiment of the present invention will be described.

FIGS. 15 to 18 are diagrams explaining a method for fabricating a semiconductor device in accordance with another embodiment of the present invention.

Referring to FIG. 15, an additional ion implant process is performed to implant impurity ions into the exposed junction area 140 of the semiconductor substrate 100. The impurity ions are indicated by slashes. The additional ion implant process is performed by a hot implant process for implanting impurity ions at a high temperature of 100 to 500° C.

As described above, when impurity ions are implanted into the semiconductor substrate by a physical ion implant process, silicon couplings within the semiconductor substrate are cut, and a plurality of defects are formed in the wafer while the cut silicon atoms are rearranged. That is, during the recrystallization, an amorphous layer may be locally formed. The amorphous layer may include residual damage, and may cause the TED of impurity ions during a subsequent heat treatment process. In this embodiment of the present invention, the hot implant process for implanting impurity ions at a high temperature is introduced to suppress the formation of the amorphous layer, thereby preventing the formation of defects.

In order to perform the additional ion implant process on the exposed junction area 140 of the semiconductor substrate 100, the semiconductor substrate 100 is disposed over a chuck (not illustrated) of an ion implant device. During the additional ion implant process, cluster ions or molecular ions containing n-type or p-type conductive impurities may be implanted. For example, the p-type conductive impurities may include B or BF₂, and the n-type conductive impurities may include P or As. The additional ion implant process may be performed in a state in which the ion implant energy is set at 1 KeV to 10 KeV and a dose rate is set at 1E13 to 1E16 ions/cm³. When impurity ions having a small molecular weight are implanted, for example, when boron (B) or carbon (C) ions are implanted, the additional ion implant process may be performed in a state in which the ion implant energy is set at 1 KeV to 10 KeV and the dose rate is set to be smaller than 1E13 ions/cm³. During the hot implant process, the semiconductor substrate 100 is heated by increasing the temperature of the chuck of the ion implant device having the semiconductor substrate 100 disposed therein in the range of 100° C. to 500° C., thereby maximizing a lattice energy of silicon during the impurity ion implant. Here, the method for heating the semiconductor substrate 100 may be performed by heating the chuck through a heating wire mounted on the chuck or heating the chuck using radiant heat. The chuck may be heated to a temperature of 130° C. to 150° C. when a resist material is applied as the ion implant barrier layer, and may be heated to 500° C. when a resist material is not applied as the ion implant barrier layer. In this case, the interlayer dielectric layer 153 serving as an ion implant barrier and may have a stacked structure of a nitride layer, an oxide layer, and an amorphous carbon layer, which are not deformed or diffused to the outside in a high-temperature state.

When the hot implant process to implant impurity ions at a high temperature of 100° C. to 500° C. is performed, the lattice energy of silicon during the ion implant process is maximized to immediately recrystallize an amorphous layer which is locally formed during the ion implant process. That is, the energy required for recrystallization is supplied to suppress the formation of the amorphous layer. Accordingly, although defects occur, the recrystallization is induced by the supplied energy. Then, as illustrated in FIG. 16 which is an expanded view of a region II including the junction area of FIG. 15, the formation of defects within the junction area 140 and the semiconductor substrate 100 is suppressed.

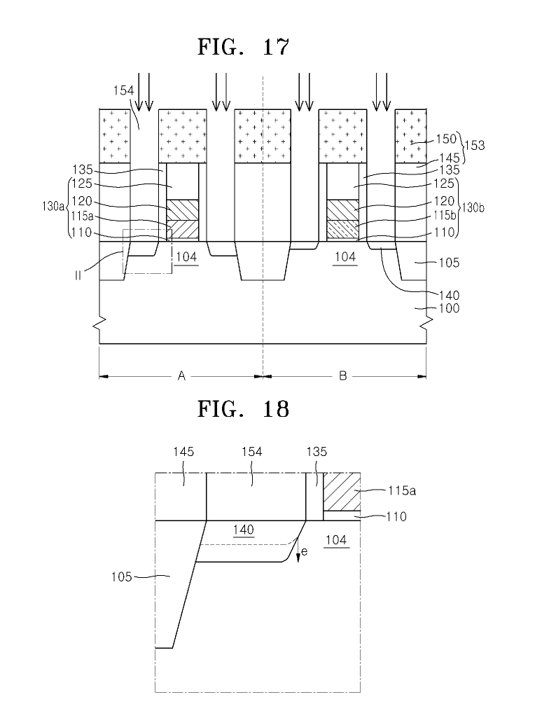

Referring to FIGS. 17 and 18, a heat treatment process is performed to activate the impurity ions implanted into the exposed junction area 140 of the semiconductor substrate 100 by the additional ion implant process. The heat treatment process may include an RTA process, but is not limited thereto. The RTA process may be performed by supplying NH₃ gas together. FIG. 18 is an expanded view of a region II including the junction area 140 of FIG. 17. Referring to FIG. 18, when the heat treatment process is performed to activate and diffuse the impurity ions implanted into the junction area 140, the thickness of the junction area 140 is increased by a first depth e in the depth direction of the semiconductor substrate 100. In this case, since defects are not formed in the semiconductor substrate 100, it is possible to prevent the TED of impurity ions caused by defects. At this time, the heat treatment process may be performed after a Ti layer is deposited as a metal layer on the exposed surface of the contact hole 154. Accordingly, a concentration of impurities existing at the surface of the junction area 140 may be secured to thereby reduce contact resistance of a metal contact which is to be subsequently formed.

Referring to FIG. 13, the contact hole 154 is filled with a metallic material to form a metal contact 170. The metal contact 170 is directly contacted with the junction area 140 of the semiconductor substrate 100, and an ohmic contact is formed to minimize contact resistance between the metal and the silicon of the semiconductor substrate 100.

In accordance with the embodiments of the present invention, the ion implant process is performed at an ultralow temperature to maximize the formation of the amorphous layer which is difficult to form under a general condition of ion implant energy and ion implant amount, thereby minimizing residual damage within the semiconductor substrate. Furthermore, since the defects which may be easily formed on the surface of the semiconductor substrate are moved under the interface between the amorphous layer and the semiconductor substrate, it is possible to suppress the TED of impurity ions. Alternatively, the ion implant process may be performed at a high temperature to suppress the formation of an amorphous layer and defects within the semiconductor substrate.

As the ion implant process is introduced to suppress the TED of impurity ions, the surface concentration of the junction area may be increased to reduce the contact resistance between the junction area and the metal contact. Furthermore, as the change in threshold voltage of the transistor caused by the change in the number of ions implanted into a unit area minimizes the fluctuation of the impurity ions, it is possible to improve the mismatch of the sense and amplifier transistor indicating an operation error degree of the device which is caused by a difference in threshold voltage between left and right transistors of the sense and amplifier transistor.

Embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for fabricating a semiconductor device, comprising:
forming an impurity junction area within an area of a semiconductor substrate;
forming a contact hole which partially exposes a surface of the impurity junction area; and
performing an additional ion implant process to implant impurity ions into the impurity junction area exposed through the contact hole, thereby increasing an impurity concentration of a surface portion of the impurity junction area.

2. The method of claim 1, further comprising, after performing the additional ion implant process:
performing a heat treatment process to diffuse the impurity ions implanted into the impurity junction area; and
filling the contact hole with a conductive material to form a contact which is directly contacted with the impurity junction area.

3. The method of claim 2, wherein the heat treatment process comprises a rapid thermal annealing (RTA) process in which ammonia (NH₃) gas is supplied together.

4. The method of claim 1, wherein performing the additional ion implant process comprises forming an amorphous layer at a first depth from the surface of the impurity junction area through a cold implant process for implanting impurity ions at an ultralow temperature of −100° C. to −200° C., such that defects formed during the additional ion implant process are positioned under the interface between the amorphous layer and the semiconductor substrate.

5. The method of claim 4, wherein the cold implant process comprises:
disposing the semiconductor substrate over a chuck of an ion implant device; and
implanting impurity ions in a state in which the semiconductor substrate is cooled to a temperature of −100° C. to −200° C. by cooling a temperature of the chuck to the temperature of −100° C. to −200° C.

6. The method of claim 5, wherein, in implanting the impurity ions, the semiconductor substrate is cooled down by flowing a refrigerant to the chuck or contacting a medium having a refrigerant flowed therein with the chuck.

7. The method of claim 1, wherein performing the additional ion implant process comprises recrystallizing defects formed during the additional ion implant process, through a hot implant process for implanting impurity ions at a temperature of 100° C. to 500° C.

8. The method of claim 7, wherein the impurity ions comprise cluster ions or molecular ions containing n-type or p-type conductive impurities.

9. The method of claim 8, wherein the n-type conductive impurities comprise phosphorous (P) or arsenide (As), and the p-type conductive impurities comprise boron (B) or BF₂.

10. The method of claim 8, wherein the impurity ions are implanted in a state in which ion implant energy is set at 1 KeV to 10 KeV and a dose rate is set at 1E13 to 1E16 ions/cm³.

11. The method of claim 7, wherein the hot implant process comprises:
disposing the semiconductor substrate over a chuck of an ion implant device; and
implanting impurity ions in a state in which the temperature of the semiconductor substrate is increased to the temperature of 100° C. to 500° C. by heating the chuck through a heating wire mounted on the chuck or heating the chuck using radiant heat.

12. A method for fabricating a semiconductor substrate, comprising:
forming an n-type poly gate and a p-type poly gate over a semiconductor substrate having an n-type area and a p-type area such that the n-type poly gate is formed in the n-type area and the p-type poly gate is formed in the p-type area;
forming a gate spacer on both side surfaces of the n-type and p-type poly gates;
forming an impurity junction area within an active area of the semiconductor substrate at both side surfaces of the n-type and p-type poly gates;
forming an interlayer dielectric layer including a contact hole which partially exposes a surface of the impurity junction area at both side surfaces of the n-type and p-type poly gates;
performing an ion implant process on the surface of the impurity junction area exposed through the contact hole to increase an impurity concentration of a surface portion of the active area, the ion implant process comprising a cold implant process or a hot implant process;
performing a heat treatment process to diffuse the impurity ions implanted into the impurity junction area; and
filling the contact hole with a conductive material to form a contact which is directly contacted with the impurity junction area.

13. The method of claim 12, wherein the cold implant process comprises implanting impurity ions at an ultralow temperature of −100° C. to −200° C. to form an amorphous layer at a first depth from the surface of the impurity junction area, such that defects formed during the additional ion implant process are positioned under the interface between the amorphous layer and the semiconductor substrate.

14. The method of claim 12, wherein, during the cold implant process, the impurity ions are implanted in a state in which the semiconductor substrate is cooled down to a temperature of −100° C. to −200° C. by flowing a refrigerant to a chuck or contacting a medium having a refrigerant flowed therein with the chuck.

15. The method of claim 12, wherein the hot implant process comprises implanting impurity ions at a temperature of 100° C. to 500° C. and recrystallizing defects formed during the additional ion implant process.

16. The method of claim 15, wherein the impurity ions comprise cluster ions or molecular ions containing n-type or p-type conductive impurities.

17. The method of claim 16, wherein the n-type conductive impurities comprise P or As, and the p-type conductive impurities comprise B or BF₂.

18. The method of claim 16, wherein the impurity ions are implanted in a state in which ion implant energy is set at 1 KeV to 10 KeV and a dose rate is set at 1E13 to 1E16 ions/cm³.

19. The method of claim 12, wherein the hot implant process comprises:
disposing the semiconductor substrate over a chuck of an ion implant device; and
implanting impurity ions in a state in which the temperature of the semiconductor substrate is increased to the temperature of 100° C. to 500° C. by heating the chuck through a heating wire mounted on the chuck or heating the chuck using radiant heat.

20. A method for fabricating a semiconductor device, comprising:
forming an impurity junction area within an area of a semiconductor substrate; and
performing at least two ion implant processes for implanting impurities into the impurity junction area, where one ion implant process is performed at a temperature that is one of less than −100° C. or greater than 100° C.
